(19) United States
(12) Patent Application Publication
(10) Pub. No.: US 2013/0234323 A1
(43) Pub. Date: Sep. 12, 2013

(54) SEMICONDUCTOR CHIP AND MANUFACTURING METHOD THEREOF

(71) Applicant: ELPIDA MEMORY, INC., Tokyo (JP)

(72) Inventor: Toru MIYAZAKI, Tokyo (JP)

(73) Assignee: ELPIDA MEMORY, INC., Tokyo (JP)

(21) Appl. No.: 13/784,305

(22) Filed: Mar. 4, 2013

(30) Foreign Application Priority Data
Mar. 8, 2012 (JP) 2012-052275

(51) Int. Cl. H01L 23/00

(52) U.S. Cl. CPC H01L 24/12; H01L 24/11
USPC 257/737; 438/614

(57) ABSTRACT

A semiconductor device comprising stacked substrates through a bump, the bump comprising a solder bump formed on a copper bump wherein the solder bump includes Zn.

### REFERENCE TO RELATED APPLICATION

This application is based upon and claims the benefit of the priority of Japanese patent application No. 2012-052275, filed on Mar. 8, 2012, the disclosure of which is incorporated herein in its entirety by reference thereto.

### TECHNICAL FIELD

The present invention relates to a semiconductor device. In particular, it relates to a semiconductor device comprising stacked substrates through bumps and to a method of manufacturing the semiconductor device.

### BACKGROUND

Regarding stacked memory chips (chip on chip, COC), after a wafer process, products each of which is cut per chip are stacked on each other. In one of the stacking methods, a through substrate via (referred to as “TSV” in the present disclosure) technique is used.

The TSV technique is used for stacking a plurality of semiconductor substrates. More specifically, chips including a via penetrating through the chips vertically (namely, in the same direction as the direction the chips are stacked) are stacked, and the stacked chips are connected to each other via a bump formed on the TSV. With this method, the stacked package can have a smaller size, when compared with a method in which chips are connected to each other by a bonding wire.

In a stacking method based on such TSV technique, for example, an SnAg (an alloy containing tin and silver, which will hereinafter be referred to as “an alloy containing tin/silver” or “a tin/silver alloy”) solder bump formed on a TSV surface side of a semiconductor chip is melted and bonded to an Au/Ni bump formed on a TSV back side of a neighboring chip. A Cu (copper) seed film is formed on such chip surface (base layer), and a Cu bump is formed at a predetermined position (a position at the TSV) by using a resist film. The SnAg solder bump is formed on the Cu bump. For example, Patent Literature 1 discloses a semiconductor chip in which an SnAg solder is formed on a Cu bump.

After the SnAg solder bump on the semiconductor chip surface side is formed, the Cu seed film (and the resist film) is removed. However, in the process of removing this Cu seed film, the Cu bump under the SnAg solder bump is also cut and retracted simultaneously. As a result, the SnAg solder bump is protruded in the form of eaves (hereinafter, this portion will be referred to as “eaves”). If left as it is, the eaves adversely affect detachability of a support (when the support is detached, defective detaching is caused due to the eaves). Therefore, by reflowing the SnAg solder bump, the eaves are removed and the solder hump is in a dome-like shape (the protruded portion is removed by melting and smoothing).
[Patent Literature 1]
Japanese Patent Kokai Publication No. JP2011-86879A

### SUMMARY

The entire disclosure of the above Patent Literature 1 is incorporated herein by reference hereto. As described above, a stacked chip manufacturing process includes an SnAg solder bump reflow process for removing eaves of the SnAg solder bump and improving detachability of the support. However, when the SnAg solder bump is reflowed, since Cu is diffused from the lower Cu bump into the SnAg solder bump, an SnAgCu alloy is formed. As a result, the melting point is increased. Thus, when a heat treatment is subsequently executed to stack (connect) chips, the SnAg solder bump is not sufficiently melted. Consequently, the electrical connection between the solder bump and Au/Ni bump of neiboring chip is insufficient, offering a problem.

In view of the above problem, as Cu diffusion prevention measures, nickel, palladium, or the like may be stacked on the Cu bump. The Cu diffusion into the SnAg solder by a reflow process executed to remove eaves of the SnAg solder is a problem on the one hand, since the Cu diffusion forms an SnAgCu alloy, increases the melting point, results in insufficient melting when chips are stacked. However, on the other hand the opposite is true after the chips are stacked. It is more preferable to diffuse Cu into the SnAg solder during a heat treatment when chips are bonded (connected), form an SnAgCu alloy having a higher Cu concentration, and increase the melting point, so that the SnAg solder of the lower stacked (connected) chip does not melt again during a heat treatment executed to stack a new chip on the chip. Thus, it is necessary to satisfy the conflicting need that a film that prevents Cu diffusion must not exist when chips are connected.

Thus there is a need in the art to provide a semiconductor chip including a Through-Substrate-Vias-connection SnAg solder bump capable of increasing a melting point through Cu diffusion into the SnAg solder after semiconductor chips are stacked (connected) while preventing Cu diffusion into the SnAg solder even when a reflow process is executed before the stacking step.

In a first aspect, a semiconductor device according to the present invention comprises a first substrate and a second substrate stacked on the first substrate through a bump, the bump comprising a solder bump formed on a copper bump formed over the second substrate, wherein the solder bump includes Zn.

In a second aspect, a method according to the present invention of manufacturing a semiconductor device comprising stacked substrates through a hump, the bump comprising a solder hump, comprises: forming a copper bump; forming a Sn/Zn alloy layer on the copper bump; forming a Sn/Ag alloy layer on the Sn/Zn alloy; and heating and reflowing the Sn/Zn alloy layer and the Sn/Ag alloy layer,

With a semiconductor chip including a solder bump configured as described above, it is possible to increase a melting point through Cu diffusion into the SnAg solder after semiconductor chips are stacked (connected together) while preventing Cu diffusion into the SnAg solder even when a reflow process is executed to remove eaves of the Through-Substrate-Vias-connection SnAg solder before the stacking step.

### BRIEF DESCRIPTION OF THE DRAWINGS

The above features and advantages of the present disclosure will be more apparent from the following description of certain preferred embodiments taken in conjunction with the accompanying drawings, in which:

FIG. 1 illustrates schematic cross sections of a process flow of a method for manufacturing solder of a semiconductor chip according to an example of the present disclosure.

FIG. 2 illustrates schematic cross sections of process flows of methods for manufacturing solder of semiconductor chips according to a conventional technique and an example of the present disclosure.

FIG. 3 illustrates a cross section of a variation of the semiconductor chip according to the example.

FIG. 4 illustrates a cross section of a semiconductor package including a plurality of semiconductor chips according to the example.

### PREFERRED MODES

In the first aspect, it is preferable that the alloy layer containing Sn, Ag, and Zn contain 1 to 5% by weight of Zn.

As described above, the alloy layer containing Sn, Ag, and Zn may further contain Bi.

In addition, the alloy layer containing Sn, Ag, and Zn may further contain Cu.

In the second aspect, it is preferable that the Sn/Zn alloy contain 1 to 5% by weight of Zn.

In addition, it is preferable that the Sn/Zn alloy layer and/or the Sn/Ag alloy layer further contain Bi.

In addition, it is preferable that the Sn/Zn alloy layer and/or the Sn/Ag alloy layer may further contain Cu.

According to the present disclosure, when the SnAg solder is formed, first, two Sn alloy layers are stacked on the Cu bump. Namely, by using an SnZn (tin/zinc alloy) layer including Zn (zinc) that does not easily react with Cu as a layer in direct contact with the Cu bump, Cu diffusion is suppressed, and an SnAg (tin/silver alloy) layer is stacked on the SnZn layer. With this configuration, since copper is mixed into the SnAg layer, an increase of the melting point is suppressed. Namely, since the solder is melted sufficiently when chips are stacked, the sufficient electrical connection is stabilized. As a result, defectively stacked chips can be reduced. The Sn/Zn alloy preferably contains approximately 1 to 10% Zn, and more preferably, approximately 1 to 5% Zn. In addition, the Sn/Ag alloy preferably contains approximately 1 to 10% Ag, and more preferably, approximately 1 to 5% Ag.

In addition, since reduction of degree of heating leads to reduction of Cu diffusion, it is more effective to use SnAgBi (tin/silver/bithmuth alloy), SnAgBiCu (tin/silver/bithmuth/copper alloy), or the like including Bi having a low melting point as material of the upper solder. During the heat treatment before the stacking step, the Cu diffusion suppressing film, for example Sn/Zn film, suppresses Cu diffusion into the SnAg solder and avoids increasing the melting point of the SnAg. And then when a heat treatment is executed to stack chips the Cu diffusion suppressing film SnZn melts along with the upper SnAg due to the higher temperature than that of the heat treatment before the stacking step and the Cu diffusion suppressing film is mixed into the SnAg solder, so that Cu diffuses into the SnAg solder and the melting point of the solder hump increases after the stacking step. Zn diffuses into the SnAg solder so that a concentration of Zn in an upper portion of the solder bump is lower than a concentration of Zn in a lower portion of the solder bump, Preferably, approximately 1 to 10% bithmuth is contained. More preferably, approximately 1 to 5% bithmuth is contained.

### EXAMPLES

### Example 1

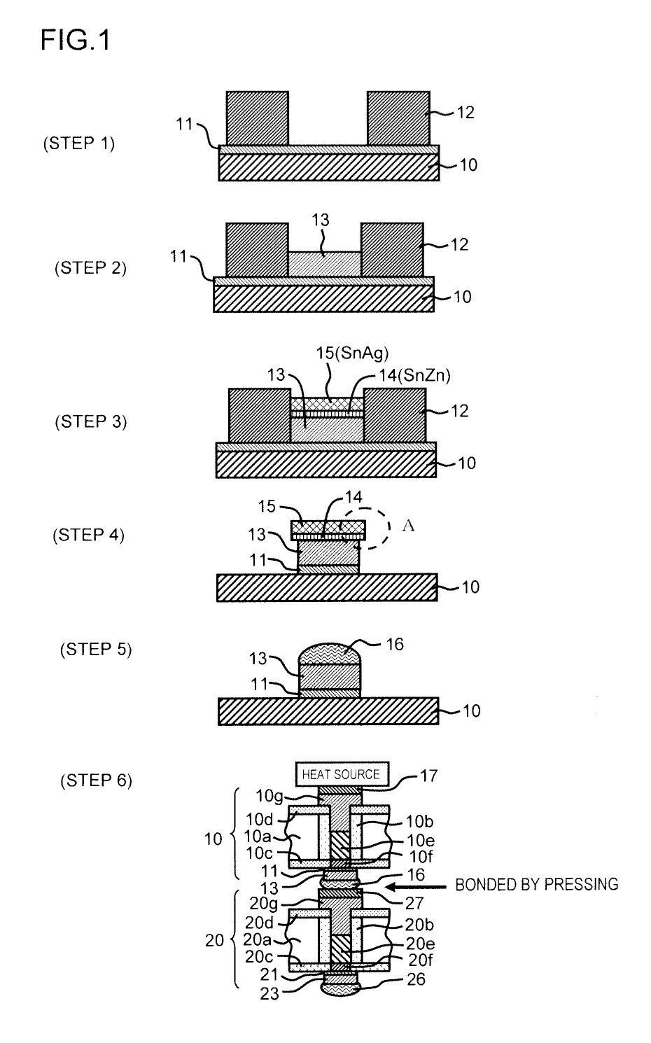

FIG. 1 illustrates a process flow for manufacturing a bump on a surface side of a semiconductor chip in which a via that penetrates the substrate is formed. In step 1, to form a solder bump 16 on a surface side (the upper side in step 1 in FIG. 1), a seed 11 (for example, a Cu seed) is formed on the entire surface of a semiconductor chip 10 serving as a base layer, and a resist film 12 having a bump pattern (an opening) is formed on the seed 11.

Next, in step 2, a surface bump 13 (for example, Cu) is formed by electroplating on the seed 11 that is exposed in the opening in the resist film 12.

Next, in step 3, two layers of solder, whose types are different from each other (for example, Sn-based alloys), are stacked on the surface bump 13 that is exposed in the opening in the resist film 12. Namely, first, an SnZn alloy layer 14 for suppressing Cu diffusion is formed on the surface bump 13, and next, an SnAg alloy layer 15 is stacked on the SnZn alloy layer 14. The SnZn alloy layer 14 and the SnAg alloy layer 15 will collectively he referred to as a stacked Sn alloy solder layer.

Next, in step 4, the resist film 12 and the seed 11 are removed.

Next, in step 5, a reflow process is executed to remove eaves (portion A) of the stacked Sn alloy solder layer (14, 15). Such eaves arc formed when the seed 11 is removed in step 4, since the side wall of the surface bump 13 formed under the stacked Sn alloy solder layer (14, 15) retracts more than the side wall of the stacked Sn alloy solder layer (14, 15). In this way, the eaves (portion A) can be smoothed roundly, and the solder bump 16 (derived from the stacked Sn alloy solder layer (14, 15)) can be formed.

Next, a back bump (corresponding to 10g in step 6) is formed on the back side (the lower side in step 5 in FIG. 1) of the semiconductor chip 10. Next, a pad 17 (for example, AuNi) is formed on a surface of the back bump 10g. Next, each semiconductor chip 10 is cut from the wafer.

Next, in step 6, the solder bump 16 on the surface side of the first semiconductor chip 10 is melted at the melting temperature thereof. In this way, the surface bump 13 of the first semiconductor chip 10 is bonded to a pad 27 on a hack side of a second semiconductor chip 20 (an equivalent of the first semiconductor chip 10) via the solder hump 16.

A via that penetrates the substrate 10e (20e; for example, Cu) is embedded in a through hole formed in a semiconductor substrate 10a (20a; for example, a silicon substrate) of the semiconductor chip 10 (20) via an insulating ring (i.e. tubular or cylindrical wall member) 10b (20b; for example, a silicon oxide film). An interlayer insulating film 10c (20c; for example, a silicon oxide film) is formed on the surface (the lower side in step 6 in FIG. 1) of the semiconductor substrate 10a (20a). A metal layer 10f (20f; for example, Cu) is embedded in a prepared hole connected to the via that penetrates the substrate 10e (20e) in the interlayer insulating film 10c (20c). The surface bump 13 (23; for example, Cu) is formed on the metal layer 10f (20f) via the seed 11 (21; for example, Cu). An interlayer insulating film 10d (20d; for example, a silicon oxide film) is formed on the back (the upper side in step 6 in FIG. 1) of the semiconductor substrate 10a (20a). The back bump 10g (20g; for example, Cu) is formed at a predetermined position on the interlayer insulating film 10d (20d). This back bump 10g (20g) extends through the prepared hole formed in the interlayer insulating film 10d (20d) and is connected to the via that penetrates the substrate 10e (20e). The pad 17 (27; for example, AuNi) is formed on the back bump 10g (20g).

In addition, the solder bump 16 is melted when heat is transmitted from a heat source to the solder bump 16 via the pad 17, the back bump 10g, the via that penetrates the substrate 10e, the metal layer 10f, the seed 11, and the surface hump 13 of the first semiconductor chip 10.

Thus, since the SnZn alloy layer 14 formed in step 3 suppresses Cu diffusion into the solder bump 16, the Cu concentration in the SnAg alloy layer 15 is reduced. As a result, since the solder is stably melted when chips are stacked, defective stacked chips can be reduced.

A certain amount of other elements may be included in the alloy layer including tin, silver, and zinc. For example, germanium or antimony of 5% or less may be included.

Next, a first advantageous effect of the present example will be described. In the present example, two layers, that is, a film capable of suppressing Cu diffusion (the SnZn alloy layer 14) and a normal solder alloy (the SnAg alloy layer 15), are used as the solder to be melt. Namely, since a Cu diffusion suppressing effect is obtained by the Cu diffusion suppressing film, the Cu concentration in the solder is reduced. Consequently, the solder is stably melted when chips are stacked, and the sufficient electrical connection is stabilized.

During the heat treatment before the stacking step, the Cu diffusion suppressing film SnZn suppresses Cu diffusion into the solder and avoids increasing the melting point of the solder. And then when a heat treatment is executed to stack chips Zn diffuses into the SnAg solder and the Cu diffusion suppressing film SnZn is mixed into the solder so that Cu diffuses into the SnAgZn alloy and the melting temperature of the solder bump increases after the stacking step. And remelting of the solder is suppressed after chips are stacked. Zn diffuses into the SnAg solder so that a concentration of Zn in an upper portion of the solder bump is lower than that of Zn in a lower portion of the solder bump. As a result, defective stacking can be reduced, counted as a second advantageous effect.

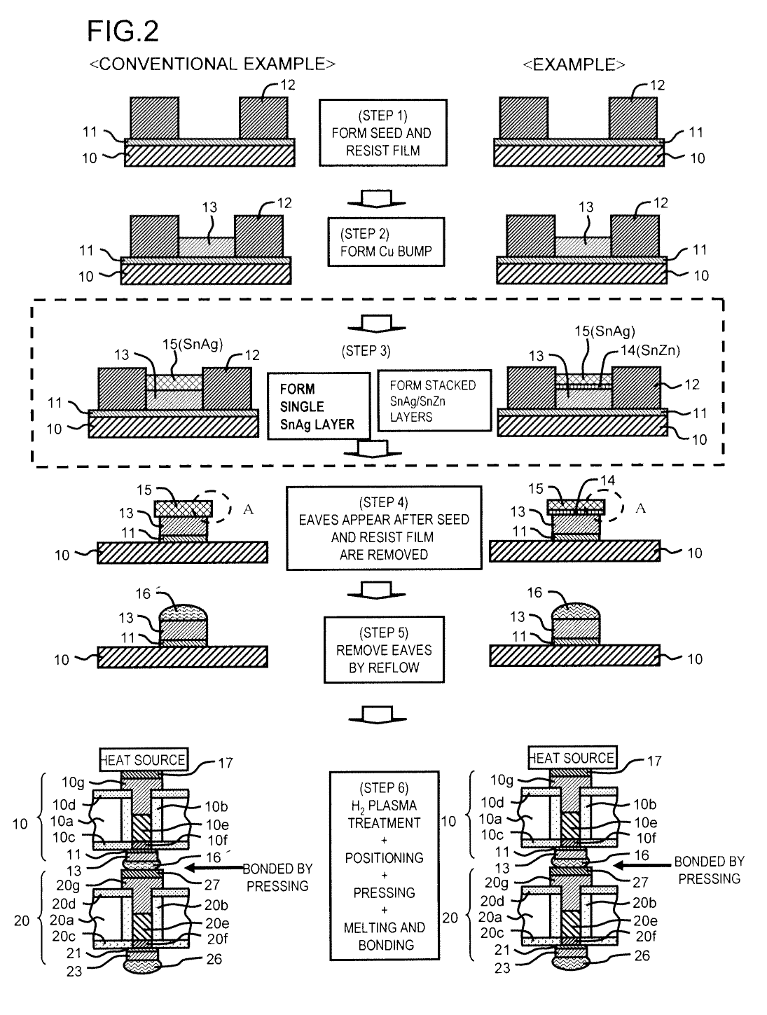

A conventional technique and example 1 of the present disclosure will be compared with reference to process flows in FIG. 2. In step 1, to form the surface-side solder bump 16 (16′), the seed 11 (for example, a Cu seed) is formed on the entire surface of the semiconductor chip 10 serving as the base layer, and the resist film 12 having a bump pattern (an opening) is formed on the seed 11. Next, in step 2, the surface bump 13 is formed by electroplating on the seed 11 that is exposed in the opening in the resist film 12. The conventional technique and the example of the present disclosure use the same steps 1 and 2.

The example of the present disclosure is different from the conventional technique in that the SnZn alloy layer 14 is formed on the surface bump 13 in step 3. According to the conventional technique, only the SnAg alloy layer 15 is formed on the surface bump 13. However, according to the example of the present disclosure, by using the property of Zn that suppresses Cu diffusion, the SnZn alloy layer 14 is formed on the surface bump 13 (Cu) and the SnAg alloy layer 15 is formed on the SnZn alloy layer 14. In addition, since reduction of the treatment temperature is effective in suppressing Cu diffusion, for example, it is effective to add Bi decreasing the melting point to the SnZn alloy layer 14 and form SnZnBi, SnAgCuBi, or the like.

Next, in step 4, the resist film 12 and the unnecessary part of the seed 11 are removed. Next, in step 5, the eaves portion A of the stacked Sn alloy solder layer (14, 15), which is formed when the seed 11 is removed, is removed by a reflow process. In the example of the present disclosure, the SnZn alloy layer 14 formed as the Cu diffusion suppressing layer needs to be removed simultaneously with the removal of the eaves.

First, the surface of the SnAg alloy layer 15 is subjected to H₂ plasma treatment to reduce and remove the oxide film on the surface of the SnAg alloy layer 15. Next, the temperature is increased to the solder melting point, and a reflow process is executed. Since the stacked Sn alloy solder layer (14, 15) is formed by two stacked layers, the temperature is increased to the higher alloy melting point, so as to simultaneously melt the two layers. In this way, simultaneously with the reflow process, the SnZn alloy layer 14 serving as the Cu diffusion suppressing film is removed (melt-mixed). When the SnZn alloy layer 14 is melted in this step 5, Cu is rapidly diffused into the SnAg alloy layer 15. Thus, this step 5 needs to be executed within a short time. In addition, to prevent oxidation of Zn, step 5 needs to be executed in an atmosphere without oxygen.

While the above reflow process is executed within the shortest possible time, the temperature needs to be managed. First, the melting temperature of the alloy having the lower melting point (for example, 210 C° if a Bi alloy is used) is set to melt the alloy having the lower melting point. Next, as soon as the melting temperature of the alloy having the higher melting point is reached (for example, 221 C°, i.e. a temperature sufficiently higher by about several to 10 centigrade, if an Sn-3.5Ag is used), heating is stopped and the temperature is decreased. In this way, it is preferable that the SnZn layer and the SnAg layer be melted, the eaves be removed, an increase of Cu diffusion from the Cu bump be prevented as much as possible.

Next, in step 6, necessary elements including the back bump (corresponding to 10g in step 6) are formed, the wafer is cut into chips by dicing, and the chips are stacked on each other. The SnAg (Zn) alloy solder bump 16 to be melted on the surface side is subjected to an H₂ plasma treatment to reduce and remove the oxide film. Next, the pad 27 of the second semiconductor chip 20, which is to be stacked on the first semiconductor chip 10, and the solder bump 16 of the first semiconductor chip 10 are positioned to each other. A certain pressure is applied to press these first and second semiconductor chips 10 and 20. Next, by heating the pad 17 of the first semiconductor chip 10, the solder hump 16 is heated via the back bump 10g, the via that penetrates the substrate 10e, the metal layer 10f, the seed 11, and the surface bump 13. By increasing the temperature of the solder hump 16 to the melting point thereof, the pad 27 of the second semiconductor chip 20 and the surface bump 13 of the first semiconductor chip 10 are connected via the solder bump 16. These operations from the removal of the oxide film on the surface of the solder bump 16, the reflow process, and to the connection of the first and second semiconductor chips 10 and 20 are executed continuously. In addition, these operations need to be executed in an atmosphere in which re-oxidation of the surface of the solder bump 16 is prevented and without contamination.

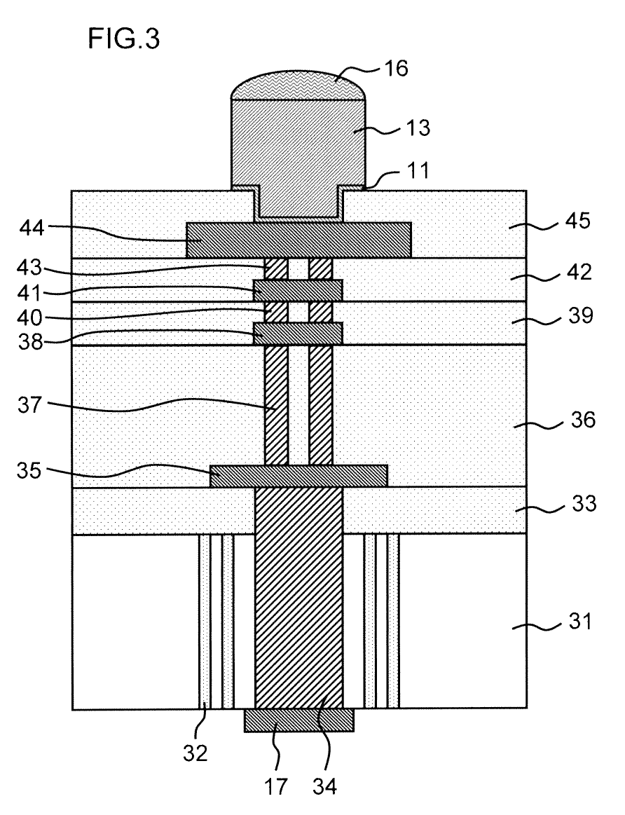

FIG. 3 illustrates a configuration of a semiconductor chip as a variant of the semiconductor chip 10 in FIG. 1. In the semiconductor chip in FIG. 3, an interlayer insulating film 33 (for example, a silicon oxide film) is formed on a semiconductor substrate 31 (for example, a silicon substrate), and a via that penetrates the substrate 34 (for example, Cu) is formed in a hole penerating through the semiconductor substrate 31 and the interlayer insulating film 33. Insulating rings 32 (for example, silicon oxide films) are formed around the via that penetrates the substrate 34 in the semiconductor substrate 31. A wiring 35 (for example, Cu) connected to the via that penetrates the substrate 34 is formed at a predetermined position on the via that penetrates the substrate 34 and the interlayer insulating film 33. An interlayer insulating film 36 (for example, a silicon oxide film) is formed on the wiring 35 and the interlayer insulating film 33. Prepared holes connected to the wiring 35 are formed in the interlayer insulating film 36, and vias 37 (for example, Cu) are embedded in the prepared holes. A wiring 38 (for example, Cu) connected to the vias 37 are formed at a predetermined position on the vias 37 and the interlayer insulating film 36. An interlayer insulating film 39 (for example, a silicon oxide film) is formed on the wiring 38 and the interlayer insulating film 36. Prepared holes connected to the wiring 38 are formed in the interlayer insulating film 39, and vias 40 are embedded in the prepared holes. A wiring 41 (for example, Cu) connected to the vias 40 is formed at a predetermined position on the vias 40 and the interlayer insulating film 39. An interlayer insulating film 42 (for example, a silicon oxide film) is formed on the wiring 41 and the interlayer insulating film 39. Prepared holes connected to the wiring 41 are formed in the interlayer insulating film 42, and vias 43 are embedded in the prepared holes. A wiring 44 (for example, Cu) connected to the vias 43 is formed at a predetermined position on the vias 43 and the interlayer insulating film 42. An interlayer insulating film 45 (for example, a silicon oxide film) is formed on the wiring 44 and the interlayer insulating film 42. A prepared hole connected to the wiring 44 is formed in the interlayer insulating film 45. The seed 11 (for example, a Cu seed) is formed at a predetermined position on the wiring 44 and the interlayer insulating film 45. The surface bump 13 is formed on the seed 11, and the solder bump 16 (obtained after reflowing the SnZn alloy and the SnAg alloy) is formed on the surface bump 13.

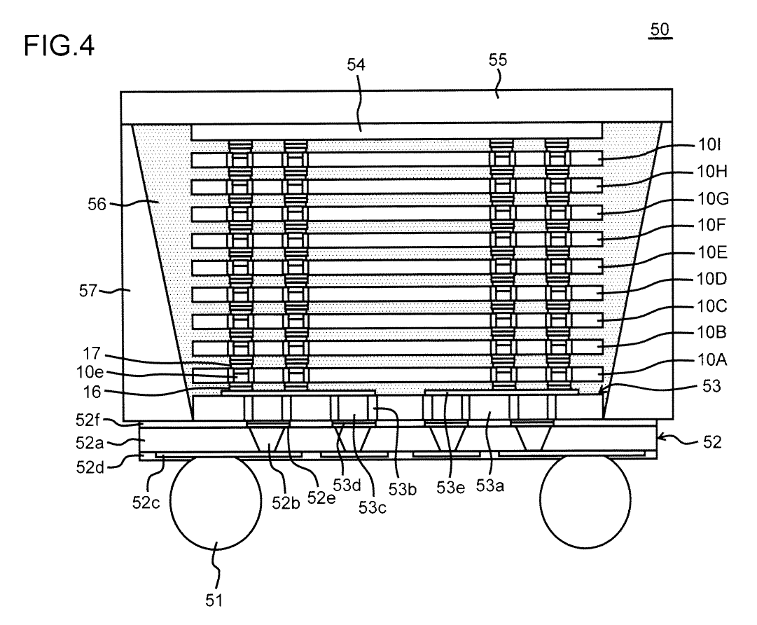

In addition, the semiconductor chip 10 according to the example is used as a stacked semiconductor package 50 as illustrated in FIG. 4. In the semiconductor package 50 in FIG. 4, a stacked body obtained by stacking semiconductor chips 10A to 10I (equivalents of the semiconductor chip in FIG. 1) manufactured in accordance with the steps in FIG. 1 is mounted on an interposer 52 via an interface chip 53. A lead frame 55 is mounted on the topmost semiconductor chip 10I via an insulating film 54. The space between the interposer 52 and the lead frame 55 (the space among the semiconductor chips 10A to 10I and the insulating film 54) is filled with an underfill 56, and a sealing resin 57 is formed around the underfill 56 between the interposer 52 and the lead frame 55.

The interposer 52 includes through holes 52b running through an insulating substrate 52a, and pads 52c connected to corresponding through holes 52b are formed at predetermined positions on a side of the insulating substrate 52a on which solder balls 51 are formed. An insulating layer 52d is formed on the pads 52c and the insulating substrate 52a. In addition, openings connected to corresponding pads 52c are formed in the insulating layer 52d, and solder balls 51 are formed on the corresponding pads 52c in the openings. The interposer 52 includes pads 52e connected to the corresponding through holes 52b at predetermined positions on the interface-chip-53 side. An insulating layer 52f is formed on the pads 52e and the insulating substrate 52a. Openings connected to the corresponding pads 52e are formed in the insulating layer 52f, and the interposer 52 is bonded to pads 53d of the interface chip 53 in the openings.

In addition, the interface chip 53 includes vias penetrating the substrate 53c, which are embedded in corresponding through holes formed in a semiconductor substrate 53a via corresponding insulating rings 53b. Pads 53d connected to the corresponding via penetrating the substrate 53c are formed at predetermined positions on the solder-ball-51 side of the semiconductor substrate 53a. The pads 53d are bonded to the corresponding pads 52e of the interposer 52. The interface chip 53 includes pads 53e connected to the vias penetrating the substrate 53c at predetermined positions on the semiconductor-chip-10A side. The pads 53e are connected to a via that penetrates the substrate 10e (to the surface bump 13 in FIG. 1, to be exact) of the semiconductor chip 10A via a corresponding solder bump 16.

The present invention has thus been described based on examples. However, modifications and adjustments of the exemplary embodiments and examples are possible within the scope of the overall disclosure (including the claims and the drawings) of the present invention and based on the basic technical concept of the present invention. Various combinations and selections of various disclosed elements (including the elements in each of the claims, examples, drawings, etc.) are possible within the scope of the claims of the present invention. That is, the present invention of course includes various variations and modifications that could be made by those skilled in the art according to the overall disclosure including the claims and the technical concept. Further, it is noted that the numerical values or ranges disclosed herein includes every intermediated value or sub-range falling therein, even without explicit recital thereof. Omission of the detailed values and/or sub-range is presented merely for simple disclosure.

What is claimed is:

1. A semiconductor device comprising:
a first substrate; and
a second substrate stacked on the first substrate through a bump,
the bump comprising a solder bump formed on a copper bump formed over the second substrate;
wherein the solder bump includes Zn.

2. The semiconductor device according to claim 1, further comprising;
a through-electrode penetrating the second substrate, the bump being electrically connected with the through-electrode.

3. The semiconductor device according to claim 1,
wherein a concentration of Zn in an upper portion of the solder bump is lower than a concentration of Zn in a lower portion of the solder bump, the lower portion of the solder bump is in contact with the copper bump.

4. The semiconductor device according to claim 1;
wherein the solder bump includes 1 to 5% by weight of Zn.

5. The semiconductor device according to claim 1;
wherein the solder bump further includes Bi

6. The semiconductor device according to claim 2;
wherein the solder bump further includes Bi.

7. The semiconductor device according to claim 1;
wherein the solder bump further includes Cu.

8. The semiconductor device according to claim 2;
wherein the solder hump further includes Cu.

9. The semiconductor device according to claim 4;
wherein the solde bump further includes Cu.

10. A method of manufacturing a semiconductor device, the semiconductor device comprising a first substrate stacked on a second substrates through a bump, the bump comprising a solder bump formed on a copper hump formed over the first substrate, the method comprising:
forming the copper bump over the first substrate;
forming a Sn/Zn alloy layer on the copper bump;
forming a Sn/Ag alloy layer on the Sn/Zn alloy; and
heating and reflowing the Sn/Zn alloy layer and the Sn/Ag alloy layer.

11. The method according to claim 10;
wherein the first substrate has a through-electrode penetrating the first substrate, and the bump is electrically connected with the through-electrode.

12. The method according to claim 10;
wherein the Sn/Zn alloy includes 1 to 5% by weight of Zn.

13. The method according to claim 10;
wherein the Sn/Zn alloy layer and/or the Sn/Ag alloy layer further includes Bi.

14. The method according to claim 11;
wherein the Sn/Zn alloy layer and/or the Sn/Ag alloy layer further includes Bi.

15. The method according to claim 12;
wherein the Sn/Zn alloy layer and/or the Sn/Ag alloy layer further includes Bi.

16. The method according to claim 10;
wherein the Sn/Zn alloy layer and/or the Sn/Ag alloy layer further includes Cu.

17. The method according to claim 11;
wherein the Sn/Zn alloy layer and/or the Sn/Ag alloy layer further includes Cu.

18. The method according to claim 12;
wherein the Sn/Zn alloy layer and/or the Sn/Ag alloy layer further includes Cu.
